(19) United States
(12) Patent Application Publication
(10) Pub. No.: US 2010/0017664 A1
(43) Pub. Date: Jan. 21, 2010

(54) EMBEDDED FLASH MEMORY TEST CIRCUIT

(75) Inventor: Woo-hyuk Jang, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/503,261

(22) Filed: Jul. 15, 2009

(30) Foreign Application Priority Data
Jul. 17, 2008 (KR) 1020080069738

(51) Int. Cl. G11C 29/12; G06F 11/27

(52) U.S. Cl. 714/719; 714/E11.169

(57) ABSTRACT

Provided is an embedded flash memory test circuit, including an embedded flash memory call array a read-only memory (ROM) built-in self test (BIST) unit, a ROM BIST control unit and a comparison unit. The embedded flash memory cell array includes multiple flash memory cells, and simultaneously outputs m pieces of read data, where m is a natural number. The ROM BIST unit generates first compressed data by compressing the m pieces of read data. The ROM BIST controller controls the ROM BIST unit. The comparison unit compares the first compressed data and expected data.

### PRIORITY STATEMENT

A claim of priority is made to Korean Patent Application No. 10-2008-0069738, filed on Jul. 17, 2008, in the Korean Intellectual Property Office, the subject matter of which is hereby incorporated by reference.

### SUMMARY

Embodiments of the invention relate to an embedded flash memory test circuit, and more particularly, to an embedded flash memory test circuit which compresses multiple pieces of read data into compressed data, and tests the compressed data.

A system-on-chip (SoC) is a highly integrated device configured to provide a system on one chip. When SoC includes an embedded flash memory array, for example, a process of testing the embedded flash memory array is needed.

According to an aspect of the present invention, there is provided an embedded flash memory test circuit, including an embedded flash memory cell array, having multiple flash memory cells, which simultaneously outputs m pieces of read data, where m is a natural number. The embedded flash memory test circuit also includes a read-only memory (ROM) built-in self test (BIST) unit, which generates first compressed data by compressing the m pieces of read data, and a ROM BIST controller which controls the ROM BIST unit. A comparison unit compares the first compressed data and expected data.

The ROM BIST unit may include multiple input signature register (MISR), which receives the m pieces of read data and generates the first compressed data in the form of a primitive polynomial. When at least one piece of read data from among the m pieces of read data is error data, the ROM BIST may generate first compressed data having a value different from the expected data, which corresponds to the m pieces of read data being normal data.

The MISR may include m adders and m latches, which are alternately arranged and connected to each other in series. The m adders may include XOR logic gates or XNOR logic gates, and the m latches may include registers or flip-flops.

The ROM BIST unit may further include a data compressor, which compresses the m pieces of read data and generates n pieces of second compressed data, where n is a natural number smaller than m. The MISR may then generate the first compressed data having a form of a primitive polynomial based on the n pieces of second compressed data. The data compressor may include multiple logic gates arranged in stages, where the logic gates in a front stage each receive the m pieces of read data, the logic gates in a next consecutive stage are connected to output terminals of the logic gates in the front stage, and the logic gates in a last stage output the n pieces of second compressed data.

The ROM BIST unit may sequentially compress the read data output m at a time, and sequentially generate pieces of first compressed data. The comparison unit may sequentially compare the sequentially generated first compressed data with corresponding expected data.

According to another aspect of the present invention, there is provided an embedded flash memory test circuit, including an embedded flash memory cell array, a joint test action group (JTAG) unit, a ROM BIST unit, a first selection unit and a comparison unit. The embedded flash memory cell array includes multiple flash memory cells. The JTAG unit sequentially shifts first serial data to the embedded flash memory cell array and sequentially receives second serial data generated by the embedded flash memory cell array. The ROM BIST unit generates first compressed data by compressing m pieces of read data generated by the embedded flash memory cell array. The first selection unit selects one of the JTAG unit and the ROM BIST unit in response to a test mode selection signal. The comparison unit compares the second serial data and expected data, or compares the first compressed data and the expected data, according to the selection result of the first selection unit.

The embedded flash memory test circuit may further include a state machine which generates a control signal and an address signal for reading data from the embedded flash memory cell array, and a second selection unit which selectively connects the embedded flash memory cell array to one of an output of the JTAG unit and an output of the state machine. The embedded flash memory test circuit may also include a tap controller which controls the JTAG unit.

### BRIEF DESCRIPTION OF THE DRAWINGS

The embodiments of the present invention will be described with reference to the attached drawings, in which:

FIG. 1 is block diagram illustrating an embedded flash memory test circuit, according to an embodiment of the present invention;

FIG. 2 is a block diagram illustrating a multiple input signature register (MISR) included in a read-only memory (ROM) built-in self test (BIST) unit illustrated in FIG. 1, according to an embodiment of the present invention;

FIG. 3 is a block diagram illustrating a ROM BIST unit illustrated in FIG. 1, according to an embodiment of the present invention;

FIG. 4 is a block diagram illustrating a data compressor illustrated in FIG. 3, according to an embodiment of the present invention;

FIG. 5 is a block diagram illustrating an embedded flash memory test circuit, according to an embodiment of the present invention; and

FIG. 6 is a flowchart of a method of testing an embedded flash memory, according to an embodiment of the present invention.

### DETAILED DESCRIPTION OF THE EMBODIMENTS

The present invention will now be described more fully with reference to the accompanying drawings, in which exemplary embodiments of the invention are shown. The invention, however, may be embodied in various different forms, and should not be construed as being limited only to the illustrated embodiments. Rather, these embodiments are provided as examples, to convey the concept of the invention to one skilled in the art. Accordingly, known processes, elements, and techniques are not described with respect to some of the embodiments of the present invention. Throughout the drawings and written description, like reference numerals will be used to refer to like or similar elements.

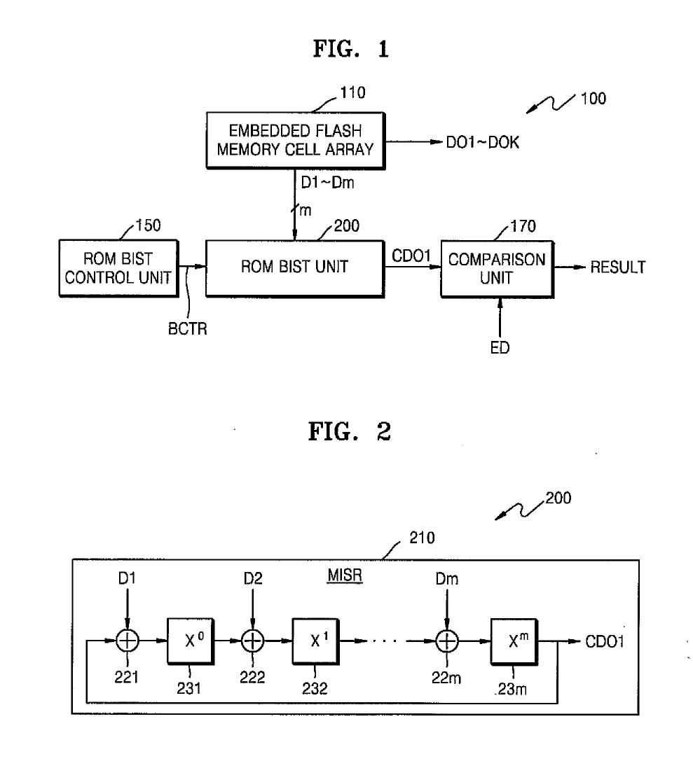

FIG. 1 is block diagram illustrating an embedded flash memory test circuit 100, according to an illustrative embodiment of the present invention.

Referring to FIG. 1, the embedded flash memory test circuit 100 includes an embedded flash memory cell array 110, a read-only memory (ROM) built-in self test (BIST) unit 200, a ROM BIST control unit 150, and a comparison unit 170.

The embedded flash memory cell array 110 includes multiple flash memory cells (not shown), and outputs m pieces of read data D1 through Dm at the same time, where m is a natural number. For example, the embedded flash memory cell array 110 may output m pieces of read data by being synchronized to a first clock, and then may output another m pieces of read data by being synchronized to a second clock. The embedded flash memory cell array 110 may repeat the above-described processes multiple times.

The ROM BIST unit 200 compresses the m pieces of read data D1 through Dm so as to generate first compressed data CDO1. The comparison unit 170 compares the first compressed data CDO1 and expected data ED, and generates a comparison result RESULT. When an error occurs in at least one of the m pieces of read data D1 through Dm, the first compressed data CDO1 indicates the error. The expected data ED is a value that the first compressed data CDO1 should have when the m pieces of read data D1 through Dm are without error. Thus, by comparing the first compressed data CDO1 and the expected data ED, it is determined whether an error has occurred in the m pieces of read data D1 through Dm. Accordingly, it is determined whether the embedded flash memory cell array 110 is operating normally.

As described above, the embedded flash memory test circuit 100 detects error(s) in the m pieces of read data D1 through Dm using the first compressed data CDO1, which is generated by compressing the m pieces of read data D1 through Dm. In other words, instead of testing each of the m pieces of read data D1 through Dm, the read data D1 through Dm are tested collectively at once by testing the first compressed data CDO1. Accordingly, a testing time of the embedded flash memory cell array 110 is reduced.

Meanwhile, the embedded flash memory cell array 110 may output read data DO1 through DOK of each of the flash memory cells in series, and the read data DO1 through DOK output in series may be sequentially tested. However, this process increases a testing time of the embedded flash memory cell array 110.

FIG. 2 is a block diagram showing a multiple input signature register (MISR) 210 included in the ROM BIST unit 200 illustrated in FIG. 1, according to an illustrative embodiment of the present invention.

Referring to FIG. 2, the MISR 210 included in the ROM BIST unit 200 generates the first compressed data CDO1 by receiving the m pieces of read data D1 through Dm. For example, the MISR 210 may generate the first compressed data CDO1 having a form of a primitive polynomial by multiplying the read data D1 through Dm by different weights. However, in alternative embodiments, the first compressed data CDO1 may have other forms.

Accordingly, the MISR 210 includes m adders 221 through 22m and m latches 231 through 23m. As illustrated in FIG. 2, the m adders 221 through 22m and the m latches 231 through 23m are alternately arranged and connected to each other in series. Since the first compressed data COD1 output by the m-th latch 23m is in the form of a primitive polynomial, the first compressed data CDO1 is different from the expected data ED when at least one of the m pieces of read data D1 through Dm has an error. Thus, it can be determined when an error occurs in the m pieces of read data D1 through Dm by comparing the expected data ED and the first compressed data CDO1 generated by the MISR 210.

The m adders 221 through 22m may include XOR logic gates or XNOR logic gates, for example. Also, the m latches 231 through 23m may include registers or flip-flops, for example.

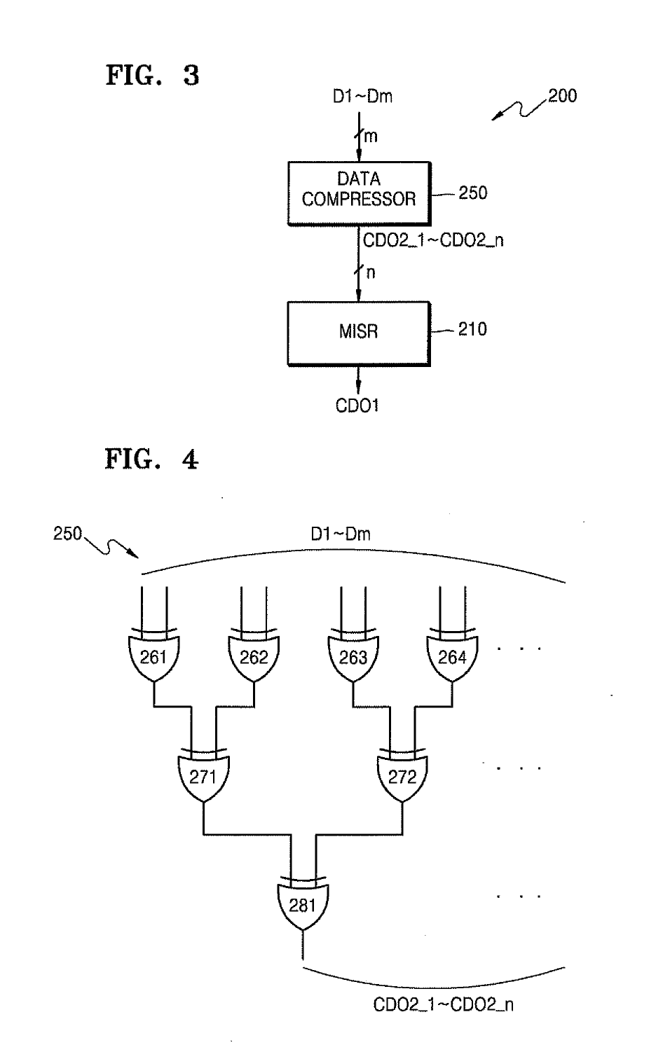

FIG. 3 is a block diagram showing the ROM BIST unit 200 of FIG. 1, according to another illustrative embodiment of the present invention.

Referring to FIG. 3, the ROM BIST unit 200 includes a data compressor 250 in addition to the MISR 210, as compared to the ROM BIST unit 200 of FIG. 3.

The data compressor 250 generates n pieces of second compressed data CDO2_1 through CDO2_n by compressing the m pieces of read data D1 through Dm, where n is a natural number smaller than m. The MISR 210 then generates the first compressed data CDO1 having a form of a primitive polynomial based on the second compressed data CDO2_1 through CDO2_n.

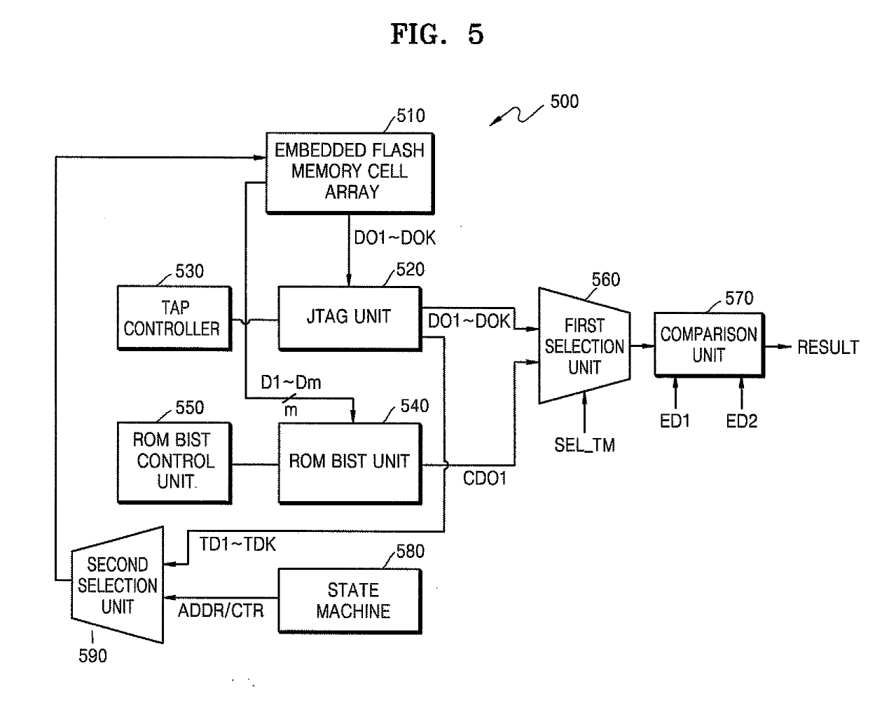

FIG. 4 is a block diagram showing in more detail the data compressor 250 of FIG. 3, according to an illustrative embodiment of the present invention.

Referring to FIG. 4, the data compressor 250 includes multiple logic gates 261 through 264, 271 through 272, and 281, respectively arranged in multiple stages. The logic gates 261 through 264, 271 through 272, and 281 may include XOR logic gates or XNOR logic gates, for example, although elements included in the logic gates 261 through 264, 271 through 272, and 281 are not limited to the depicted representative configuration in various embodiments. Likewise, in FIG. 4, the logic gates 261 through 264, 271 through 272, and 281 are arranged in three stages, although the number of stages is not limited to three in various embodiments.

The logic gates 261 through 264 in a first stage perform a logic operation by receiving the m pieces of read data D1 through Dm. The logic gate 271 in a second stage performs a logic operation on outputs of the logic gates 261 and 262 of the first stage, and the logic gate 272 in a second stage performs a logic operation on outputs of the logic gates 263 and 264 of the first stage. The logic gate 281 in a third stage generates the second compressed data CDO2_1 through CDO2_n by performing a logic operation on outputs of the logic gates 271 and 272 of the second stage. Through the above processes, the m pieces of read data D1 through Dm are compressed to the n pieces of second compressed data CDO2_1 through CDO2_n.

The number of pieces of second compressed data CDO2_1 through CDO2_n is based on the number of stages and/or logic gates 261 through 264, 271 through 272, and 281, and thus may be changed by changing the number of stages and/or logic gates 261 through 264, 271 through 272, and 281.

The ROM BIST unit 200 sequentially generates the first compressed data CDO1 by sequentially compressing the read data D1 through Dm output m at a time. The comparison unit 170 of FIG. 1 may sequentially compare the sequentially generated first compressed data CDO1 with corresponding expected data ED. In other words, by repeating the above processes, multiple pieces of read data are tested in units of m. Accordingly, the read data of the embedded flash memory cell array 110 is tested in multiple units, according to a data reading unit of the embedded flash memory cell array 110.

FIG. 5 is a block diagram showing an embedded flash memory test circuit 500, according to another illustrative embodiment of the invention.

Referring to FIG. 5, the embedded flash memory test circuit 500 includes an embedded flash memory cell array 510, a joint test action group (JTAG) unit 520, a ROM BIST unit 540, a first selection unit 560, and a comparison unit 570. The embedded flash memory cell array 510 includes multiple flash memory cells (not shown).

The JTAG unit 520 sequentially shifts first serial data TD1 through TDK to the embedded flash memory cell array 510 (e.g., through a second selection unit 590), and sequentially receives second serial data DO1 through DOK generated by the embedded flash memory cell array 510. When the second serial data DO1 through DOK received in the JTAG unit 520 has a different data value from an expected value (e.g., as determined by comparison unit 570), it is determined that the embedded flash memory cell array 510 is not operating normally.

Meanwhile, the ROM BIST unit 540 generates first compressed data CDO1 by compressing m pieces of read data D1 through Dm output from the embedded flash memory cell array 510. A ROM BIST control unit 550 controls the operations of the ROM BIST unit 540.

The first selection unit 560 selects output from one of the JTAG unit 520 and the ROM BIST unit 540 in response to a test mode selection signal SEL_TM. According to the selection of the first selection unit 560, the comparison unit 570 compares the second serial data DO1 through DOK and corresponding expected data ED1 when the JTAG unit 520 is selected, and compares the first compressed data CDO1 and corresponding expected data ED2 when the ROM BIST unit 540 is selected.

The embedded flash memory test circuit 500 according to the current embodiment may further include a state machine 580 and a second selection unit 590. The state machine 580 generates a control signal CTR and an address signal ADDR for reading data from the embedded flash memory cell array 510.

The second selection unit 590 selectively connects the embedded flash memory cell array 510 to one of an output of the JTAG unit 520 and an output of the state machine 580. When the output of the state machine 580 is connected to the embedded flash memory cell array 510, a general reading operation of the embedded flash memory cell array 510 is performed. When the output of the JTAG unit 520 is connected to the embedded flash memory cell array 510, the first serial data TD1 through TDK is sequentially shifted to the embedded flash memory cell array 510.

The embedded flash memory test circuit 500 may further include a tap controller 530 which controls the JTAG unit 520. For example, the tap controller 530 receives a clock signal via a TCK pin (not shown), and receives a test mode selection (TSM) signal that determines a state of the tap controller 530 via a TMS pin (not shown). Also, the JTAG unit 520 may receive a predetermined command via a TD1 pin (not shown). The predetermined command may determine information to be input to the embedded flash memory cell array 510. The tap controller 530 outputs signals for testing to the JTAG unit 520 in response to received clock, selection and/or command signals.

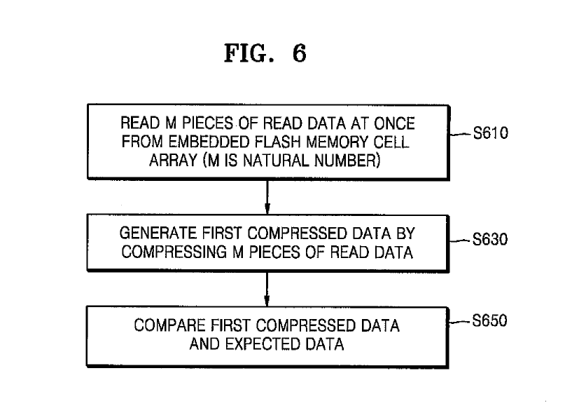

FIG. 6 is a flowchart of a method of testing an embedded flash memory, according to an illustrative embodiment of the present invention.

Referring to FIG. 6, the method includes reading m pieces of read data simultaneously from an embedded flash memory cell array, in operation S610, where m is a natural number. In operation S630, first compressed data is generated by compressing the m pieces of read data. The first compressed data and expected data are compared operation S650. The expected data is determined based on the m pieces of read data being normal.

Referring to operation S630, the first compressed data may have a form of a primitive polynomial generated by receiving the m pieces of read data. When the comparison in operation S650 shows that the first compressed data and the expected data have different values, then it is determined that at least one of the m pieces of read data is erroneous and thus the embedded flash memory cell array 110 is not operating normally. Conversely, when the comparison in operation S650 shows that the first compressed data and the expected data have the same value, then it is determined that none of the m pieces of read data is erroneous and thus the embedded flash memory cell array 110 is operating normally.

In other words, when an error occurs in at least one of the m pieces of read data, the first compressed data indicates the error. When the m pieces of read data are without error, the value of the first compressed data is the value of the expected data. Accordingly, it may be determined whether the m pieces of read data include an error by comparing the first compressed data and the expected data.

As described above, the method of testing an embedded flash memory according to the illustrative embodiment detects error(s) in the m pieces of read data using the first compressed data generated by compressing the m pieces of read data. Instead of testing each of the m pieces of read data, the m pieces of read data are tested at once using the first compressed data. Accordingly, efficiency of testing of the embedded flash memory cell array is improved, for example, by reducing the testing time.

Also as described above, the method may further include generating n pieces of second compressed data by compressing the m pieces of read data, where n is a natural number smaller than m. In this case, operation S630 may include generating the first compressed data having a form of a primitive polynomial by receiving the n pieces of second compressed data. Likewise, operation S650 would include comparing the second compressed data and respective expected data, which corresponds to the second compressed data without error.

While the present invention has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. An embedded flash memory test circuit, comprising:
an embedded flash memory cell array, comprising a plurality of flash memory cells, which simultaneously outputs m pieces of read data, wherein m is a natural number;
a read-only memory (ROM) built-in self test (BIST) unit which generates first compressed data by compressing the m pieces of read data;
a ROM BIST controller which controls the ROM BIST unit; and
a comparison unit which compares the first compressed data and expected data.

2. The embedded flash memory test circuit of claim 1, wherein the ROM BIST unit comprises a multiple input signature register (MISR) which receives the m pieces of read data and generates the first compressed data having a form of a primitive polynomial.

3. The embedded flash memory test circuit of claim 2, wherein when at least one piece of read data from among the m pieces of read data is error data, the ROM BIST generates first compressed data having a value different from the expected data, which corresponds to the m pieces of read data being normal data.

4. The embedded flash memory test circuit of claim 2, wherein the MISR comprises m adders and m latches, which are alternately arranged and connected to each other in series.

5. The embedded flash memory test circuit of claim 4, wherein the m adders comprise XOR logic gates or XNOR logic gates, and the m latches comprise registers or flip-flops.

6. The embedded flash memory test circuit of claim 2, wherein the ROM BIST unit further comprises a data compressor, which compresses the m pieces of read data and generates n pieces of second compressed data, wherein n is a natural number smaller than m, and the MISR generates the first compressed data having a form of a primitive polynomial based on the n pieces of second compressed data.

7. The embedded flash memory test circuit of claim 6, wherein the data compressor comprises a plurality of logic gates arranged in a plurality of stages, wherein the logic gates in a front stage each receive the m pieces of read data, the logic gates in a next consecutive stage are connected to output terminals of the logic gates in the front stage, and the logic gates in a last stage output the n pieces of second compressed data.

8. The embedded flash memory test circuit of claim 1, wherein the ROM BIST unit sequentially compresses the read data output m at a time, and sequentially generates a plurality of pieces of first compressed data, and the comparison unit sequentially compares the sequentially generated first compressed data with corresponding expected data.

9. An embedded flash memory test circuit, comprising:
an embedded flash memory cell array comprising a plurality of flash memory cells;
a joint test action group (JTAG) unit which sequentially shifts first serial data to the embedded flash memory cell array and sequentially receives second serial data generated by the embedded flash memory cell array;
a read-only memory (ROM) built-in self test (BIST) unit which generates first compressed data by compressing m pieces of read data generated by the embedded flash memory cell array;
a first selection unit which selects one of the JTAG unit and the ROM BIST unit in response to a test mode selection signal; and
a comparison unit which compares the second serial data and expected data or compares the first compressed data and the expected data, according to the selection result of the first selection unit.

10. The embedded flash memory test circuit of claim 9, further comprising:
a state machine which generates a control signal and an address signal for reading data from the embedded flash memory cell array; and
a second selection unit which selectively connects the embedded flash memory cell array to one of an output of the JTAG unit and an output of the state machine.

11. The embedded flash memory test circuit of claim 9, further comprising a tap controller which controls the JTAG unit.
